(19) United States
(12) Patent Application Publication
(10) Pub. No.: US 2008/0254219 A1
(43) Pub. Date: Oct. 16, 2008

(54) Method And Device For Preparing Powder On Which Nano Metal, Alloy, And Ceramic Particles Are Uniformly Vacuum-Deposited

(75) Inventors: Seok Keun Koh, Seoul (KR); Young Whoan Beag, Seoul (KR); Jun Sik Cho, Seoul (KR); Jae Ho Joo, Seoul (KR); Young Gun Han, Seoul (KR); Jung Hwan Lee, Seoul (KR); Un Jung Yo, Seoul (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: P & I CORPORATION, Seoul (KR)

(21) Appl. No.: 12/067,901

(22) PCT Filed: Oct. 16, 2006
(86) PCT No.: PCT/KR2006/004167

§ 371 Date: Mar. 24, 2008

(30) Foreign Application Priority Data
Oct. 26, 2005 (KR) 1020050101112

(51) Int. Cl. C23C 16/44

(52) U.S. Cl. 427/255.25; 118/723 VE

(57) ABSTRACT

The present invention relates to a method and device for preparing powder by depositing nano metal, alloy, ceramic particles that are excellent in size uniformity, on a surface of the powder that is a base, using a vacuum deposition method. In particular, the present invention provides a method and device for preparing the powder on which the nano metal, alloy, and ceramic particles of a very uniform size are deposited, by simultaneously performing deposition and agitation using an effective agitation means for solving a disadvantage of a conventional method where deposition and agitation are separately performed. Also, the present invention provides a method and device for preparing the powder on which nano particles are deposited, in which a nano characteristic is kept by preventing a coalescence phenomenon of nano particles even when a deposition time for increasing contents of the nano particles increases in their preparation.

### TECHNICAL FIELD

The present invention relates to a method and device for preparing powder by uniformly vacuum-depositing nano metal, alloy, and ceramic particles on a surface of the powder that is a base, using a vacuum deposition method, and more particularly, to a method and device for preparing powder on which nano particles are deposited, by uniformly forming the nano particles on a surface of the powder basis using physical and chemical vacuum deposition methods.

### BACKGROUND ART

As particles get small by a nano size (100 nm or less), nano particles have new mechanical, chemical, electric, magnetic, and optical properties different from those of existing micrometer-unit particles. This is a phenomenon appearing as a ratio of surface area to unit volume increases to an extreme. A new application field, which could not be obtained by the existing micrometer-size particles, is being steadily developed using such a quantum size effect, and its academic and technological concern is being increasingly drawn.

As a conventional typical method for preparing nano particles, there are a mechanical grinding method, a fluid precipitation method, a spray method, a sol-gel method, and an electric explosion method. However, the conventional nano-particles preparing methods have a drawback that they require several work processes or limit material for preparing the nano particles, respectively. In the nano particles prepared by the conventional method, coalescence between them easily occurs, thereby making a size non-uniform. In case where an additive such as a surfactant or a dispersant is used for preventing it, there occurs a drawback that the prepared nano particles contain a large amount of impurities, thereby deteriorating the nano particles in purity. As a method for preparing high-purity nano particles, there is a typical method for evaporating metal or ceramic in a vacuum using a dry deposition method and then, condensing and collecting the evaporated metal or ceramic on a cold wall. However, this method is not suitable to a mass production of the nano particles, and is very difficult to control the nano particles in size and uniformity.

In order to solve the drawback of the conventional method, this applicant has provided a method for depositing nano particles on powder that is a base, using a vacuum deposition method in Korean Patent Application No. 10-2004-0013826. This method solves the drawback of the occurrence of coalescence made between the nano particles by directly depositing the nano particles on the powder using the vacuum deposition method, and has an advantage of obtaining nano-particles based on very high purity. Also, it is possible to prepare a multi-function powder by depositing the nano particles with different functions on a functional powder. In the conventional method provided by this applicant, a step of depositing metal or ceramic on the powder base in a static state and a step of mixing the powder having the metal or ceramic deposited are separately and stepwise performed and are repeatedly performed, thereby forming the nano particles of a desired size on a surface of the powder. However, the conventional method has a disadvantage that the nano particles are not uniform in size and are discontinuously formed over a whole of the powder. Also, the conventional method has a drawback that the separation of the deposition and mixing steps causes a complex preparation process and an increase of a preparation time, and it is difficult to increase contents of the nano particles, and it is not easy for mass production. A detailed description of the drawback of the conventional method will be made as follows.

FIG. 1 is a scanning electron microscope photograph showing conventional nano silver particles provided on alumina powder. As shown in FIG. 1, it can be appreciated that small nano silver particles of 2 nm or less are formed and nano silver particles of 20 nm or more are also formed, thereby making a nano particle size non-uniform. This results from the fact that, since the powder is in a static state at the time of depositing the nano particles, the particles coming from a deposition source are different in amount depending on a shape or position of the powder, and, when a time for exposure to the deposition source gets longer than a time necessary for forming the desired size of the nano particles, the nano particles are arbitrarily increased in size. Accordingly, a time for depositing the nano particles in the static state is limited, and, after the deposition, a mixing process is performed and then a process of depositing the nano particles in the static state is again performed. Thus, in the powder having the nano particles earlier formed, as the deposition time increases, coalescence between them is caused, and the nano particles increase at a micro size or more and lose a nano characteristic. Thus, the deposition time is limited to before the occurrence of the coalescence, thereby causing a problem in increasing the contents of the nano particles to the extent required for application. This cause results in a drawback that, in a conventional agitator of FIG. 2 being of a flat bottom type not a present barrel type and agitating the powder on a plane, when agitation is performed, not being perfectly hidden, the powder already exposed to a deposition zone before the agitation is again exposed to the deposition zone. This acts as a key cause making it difficult to achieve a main object of the present invention for uniformly generating the nano particles on the surface of the powder.

### DISCLOSURE

### Technical Problem

Accordingly, the present invention is directed to a method and device for preparing powder on which nano metal, alloy, and ceramic particles are uniformly vacuum-deposited, that substantially obviates one or more of the problems due to limitations and disadvantages of the related art.

An object of the present invention is to provide a method and device for preparing powder on which nano metal, alloy, and ceramic particles of a very uniform size are deposited, by simultaneously performing deposition and agitation using an effective agitation means for solving a disadvantage of a conventional method where deposition and agitation are separately performed.

Another object of the present invention is to provide a method and device for preparing powder on which nano particles are deposited, in which a nano characteristic is kept by preventing a coalescence phenomenon of nano particles even when a deposition time for increasing contents of the nano particles increases in their preparation.

### Technical Solution

To achieve these and other advantages and in accordance with the purpose of the present invention, as embodied and broadly described, there is provided a method and device for uniformly depositing nano particles of such as metal, alloy, and ceramic on a surface of a powder base using a vacuum deposition method. The prepared powder having nano particles deposited according to the present invention not only has its own functionality but also has a feature of providing a functionality of the deposited nano particles together. Thus, the powder can be applied to various industrial fields, and can create a greater additional value than conventional powder.

Specifically, the present invention relates to a method in which the powder is agitated in three dimension using a barrel type agitator having a sufficient depth comparing to a powder size, so that a time for exposure to a deposition zone is minimized, and a time until the powder having the nano particles already formed is again exposed to the deposition zone is lengthened to maximize a motion of the powder base comparing to a conventional agitator, thereby suppressing coalescence between the earlier formed nano particles and new particles reaching from a deposition source, and maximally forming the nano particles. In other words, a conventional art is based on a concept in which nano particles are formed by controlling an exposure time in a static state. On contrary, the present invention is a completely new type method where nano particles are formed in a dynamic state and thus, a size of the nano particles is greatly influenced by an agitation speed. In the conventional art also, an amount of powder exposed to a plane is limited and thus, causes a limitation of an amount of one-time treatable powder. However, in the present invention, the agitation and the deposition are simultaneously performed using the barrel type agitator having a great depth, thereby solving even a mass production problem.

### ADVANTAGEOUS EFFECTS

The present invention provides a device and a technology for preparing nano metal, alloy, and ceramic particles that are excellent in size uniformity, on a surface of a powder type base, using a vacuum deposition method. The present invention has an advantage that a high purity is obtained by using a vacuum deposition method, and no observation of a general cohesion phenomenon is made among the nano particles by performing a nano deposition on powder basis, thereby maximizing a nano effect. Various vacuum deposition methods can be used, and most materials such as metal, alloy, and ceramic can be formed as the nano particles. A production process can be highly simplified owing to the absence of chemical processing. By adjusting independently controllable process variables such as a sputtering power, a vacuum degree, and an agitation speed, a product having an excellent reproducibility can be prepared. In addition to a functionality of the existing powder base, a functionality of the nano particle is added, thereby making it possible to prepare multi-function powder. This is expected to be variously applicable to energy conversion field, fuel cell, and nitrogen compound decomposition-purposed catalyst fields, as well as daily commodities, wastewater processing, and optical catalyst fields requiring the anti-bacteria and sterilization.

### DESCRIPTION OF DRAWINGS

FIG. 1 is a SEM photograph illustrating nano silver particles formed on alumina powder according to a conventional art;

FIG. 2 a conceptual view illustrating a powder agitating device and a nano-particle preparing device according to a conventional art;

FIG. 3 is a schematic diagram illustrating a preparing device for depositing nano particles according to the present invention;

FIG. 4 is a schematic perspective view illustrating an agitating unit according to the present invention;

FIG. 5 is a SEM photograph illustrating nano silver particles deposited on alumina powder according to an exemplary embodiment of the present invention;

FIG. 6 is a graph of an XPS analysis result illustrating a chemical state of nano silver particles deposited on alumina powder according to an exemplary embodiment of the present invention;

FIGS. 7A and 7B are a SEM photograph illustrating a surface of alumina powder before deposition, and a SEM photograph illustrating a surface of alumina powder observed with an evaporation amount and a deposition time maximized according to an exemplary embodiment of the present invention, respectively;

FIGS. 8A and 8B are a photograph and a graph of a chemical composition analysis result illustrating a surface of alumina powder on which nano particles are not deposited, and a photograph and a graph of a chemical composition analysis result illustrating a surface of alumina powder on which nano particles are deposited according to an exemplary embodiment of the present invention, respectively;

FIG. 9 is a graph illustrating an XPS measurement result obtained by measuring silver contents of nano silver particles that are deposited on alumina powder depending on a deposition time according to an exemplary embodiment of the present invention;

FIGS. 10A to 10E are practical photographs illustrating alumina powder on which nano silver particles are deposited depending on an increase of the same deposition time as FIG. 9, respectively;

FIGS. 11A to 11B are a photograph illustrating an anti-bacteria test result of a soap sample to which nano silver particles are not added, and a photograph illustrating an anti-bacteria test result of a soap sample prepared by mixing sugar on which nano silver particles are deposited according to another exemplary embodiment of the present invention, respectively; and

FIGS. 12A to 12F are practical photographs illustrating powder samples of sugar, salt, activated charcoal, Al₂O₃, sand, and PE chip on which nano particles are formed, respectively.

### BEST MODE FOR CARRYING OUT THE INVENTION

Hereinafter, preferred embodiments of the present invention will be described in detail with reference to accompanying drawings.

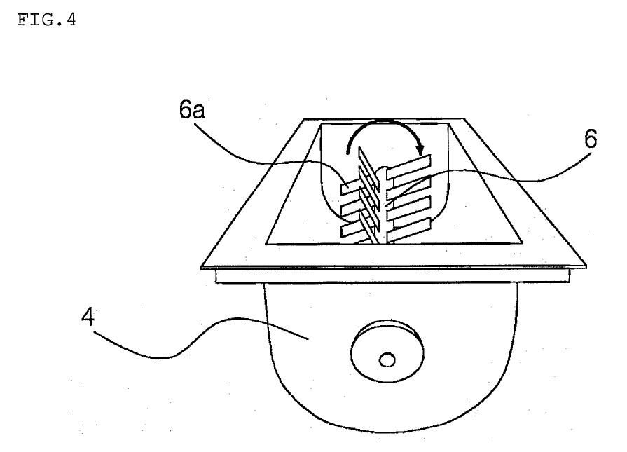

FIG. 3 is a schematic diagram illustrating a device for depositing nano particles according to the present invention, and FIG. 4 is a schematic perspective view illustrating an agitating unit according to the present invention. The inventive preparing device for depositing the nano particles of such as metal, alloy, and ceramic on a surface of powder that is a base, using a vacuum deposition method, includes a vacuum chamber 1 for forming and keeping a vacuum; and a low vacuum pump 3 and a high vacuum pump 2 connecting to one exterior side of the vacuum chamber 1; the agitating unit including a barrel 4 for containing powder and an impeller 6 for agitating the powder; a deposition unit 8 for vacuum-depositing material such as metal, alloy, and ceramic; a heating unit 9 for pre-treating the powder; a cold trap 10 for eliminating moisture from the powder; and a shield 7 for preventing the powder from diffusing outside the agitating unit at the time of agitation.

The barrel 4 is formed of material such as a stainless material that is excellent in abrasion resistance and corrosion resistance and harmless to a human body. A coolant circulation passage 5 is installed outside the barrel 4. The coolant circulation passage 5 supplies a coolant and offsets a heat generated from the deposition unit, thereby maximally preventing the powder having a weak heat resistance from being damaged by the heat.

As shown in FIG. 4, the impeller 6 preferably includes a plurality of wings 6a on its circumferential surface so that the powder can be uniformly mixed within the barrel 4. The impeller 6 rotates in a one way-direction, and is made of materials that are excellent in abrasion resistance, corrosion resistance, and heat resistance and are harmless to the human body. Among them, the stainless material can be typically used. The impeller 6 can be variously selected in shape depending on powder kind. The impeller 6 is shaped to allow the powder to be uniformly mixed to the maximum.

The deposition unit 8 can use an existing known vacuum deposition method, such as physical vapor deposition (PVD) or chemical vapor deposition (CVD), based on a magnetron sputter using a power supply such as DC/RF/MF, an ion beam sputter using an ion gun, and a heat evaporator using resistance heating or electron beam. Among them, the DC/RF/MF magnetron sputter can be most easily used. The vacuum chamber 1 can be variously selected in material to have less out-gassing and endure a high pressure. Typically, the vacuum chamber 1 can employ the stainless material.

In the present invention, a vacuum pump is comprised of the low vacuum pump 3 and the high vacuum pump 2. The vacuum pump employs only the low vacuum pump 3, or employs the low vacuum pump 3 and the high vacuum pump 2 together, depending on a required degree of work vacuum. The low vacuum pump 3 can employ a piston pump, a rotary pump, a booster pump, and a dry pump. The high vacuum pump can employ an oil diffusion pump, a turbo pump, and a cryogenic pump. The barrel or vacuum deposition unit can be varied in number depending on an amount of production. The low vacuum pump 3 or high vacuum pump 2 can be together used in plural for a quick work, thereby being optimized in number.

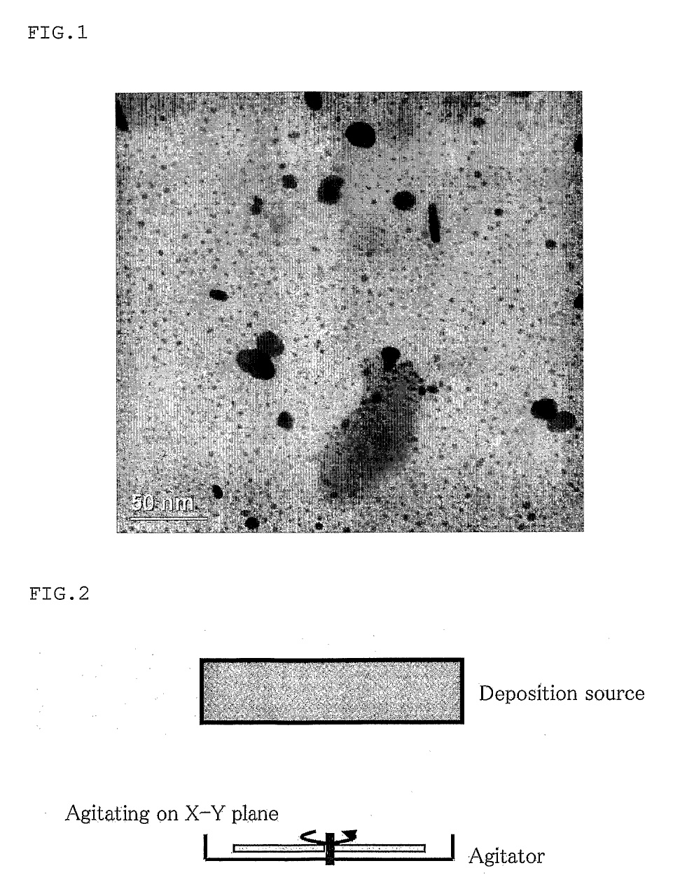

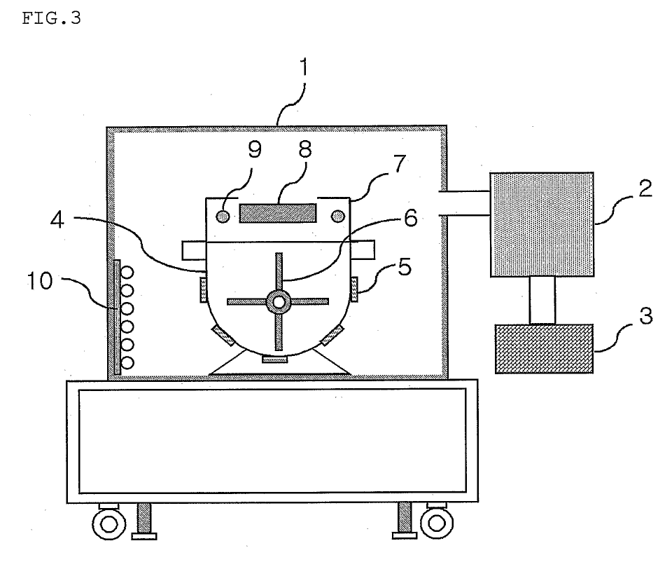

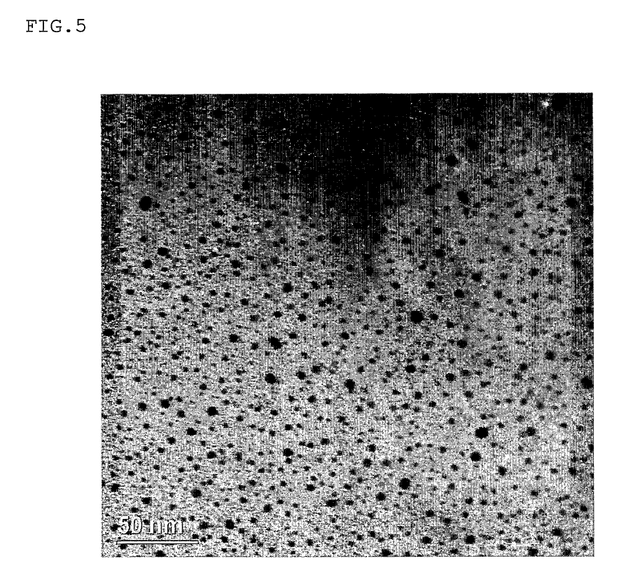

FIG. 5 is a scanning electron microscope (SEM) photograph illustrating nano silver particles deposited on alumina powder according to an exemplary embodiment of the present invention. It can be appreciated that nano particles are uniform in size between 5 nm to 10 nm comparing to FIG. 1. The nano particles are improved in uniformity because they are continuously and effectively agitated within the barrel, thereby making an exposure time of a powder surface constant, respectively, and thus, uniformly controlling the number of deposited silver atoms. The deposition particles forming a critical nucleus of a predetermined size on a surface are provided in a stable state. By the exposure time, deposition atoms forming a cluster can be controlled in number and thus, the formed nano particles can be controlled in size.

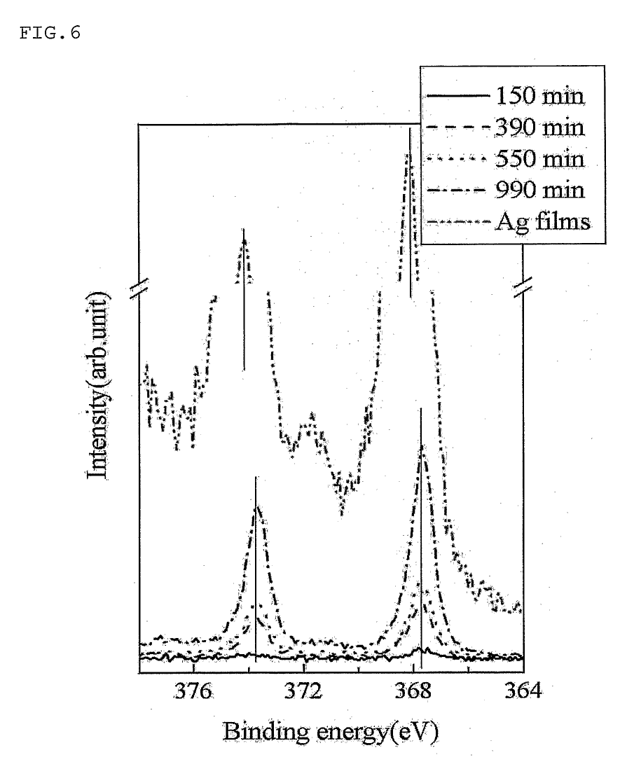

FIG. 6 is a graph of an X-ray photoelectron spectroscopy (XPS) analysis result illustrating a chemical state of the nano silver particles that are deposited on the alumina powder by the inventive device. An XPS analysis was performed on the basis of a peak of Ag 3d, and a chemical state of a silver film deposited on a glass substrate was compared and analyzed for comparison. A position of the XPS Ag 3d peak of the nano silver particles, which are prepared by agitating the alumina powder with the silver deposition time increasing from 150 minutes to 990 minutes, is constantly kept even when the deposition time increases, and is different from a peak position of the silver film deposited on the glass. On contrary, peak intensity and area are gradually increased. This means an increase of deposition silver contents. As the deposition time increases, peak intensity and area increase whereas the peak position does not vary. This means that, though the deposition time increases, the nano silver particles deposited on the alumina powder do not increase in size, and the nano silver particles increase in number by a small nano-particle type. Thus, it can be appreciated that, though the deposition time increases on the whole, the nano silver particles deposited with the powder agitated are kept in a very small nano-particle type, not a film type. This is because the effective agitation of the powder causes the shortening of the time for exposing the powder based on the static state to the deposition source, and the continuous motion of the powder causes a formation of new nano particles rather than a growth of the nano particles.

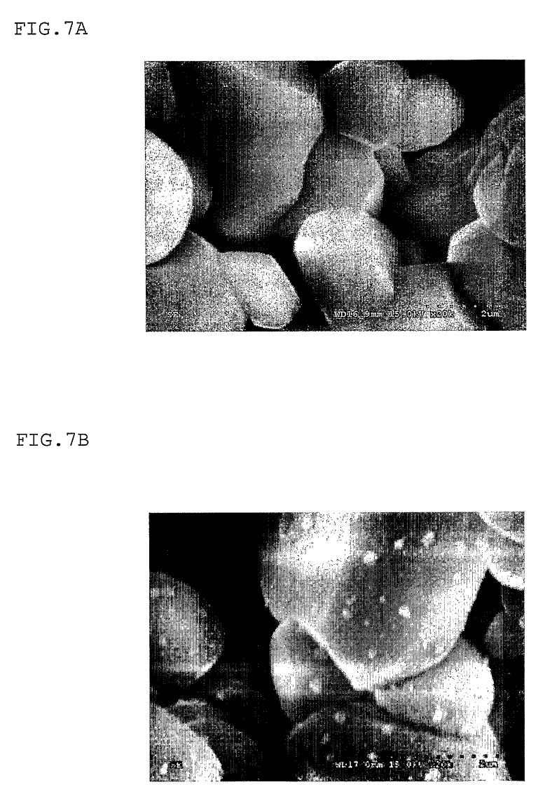

The size of the nano particles has a close relationship with an amount of the nano particles that are vaporized from the deposition source. As the deposition time increases, the nano particles can be controlled in size and amount. FIGS. 7A and 7B are a SEM photograph illustrating a surface of alumina powder before deposition, and a SEM photograph illustrating a surface of alumina powder observed with an vaporized amount and a deposition time maximized according to an exemplary embodiment of the present invention, respectively. As shown in FIG. 6B according to an exemplary embodiment of the present invention, the nano silver particles grown in size are observed, and have a size of about 10 nm to 20 nm. As observed in FIGS. 5 and 6, in case where the deposition time is within a predetermined time range, it is possible to grow the nano particles having a size of about 10 nm or less. As the deposition amount and the deposition time are maximized, it is also possible to increase the size of the nano particles, and grow the nano particles having a size of about 200 nm. However, it can be appreciated that, even when the nano particles are grown in size, a distribution of a whole particle size is very constant.

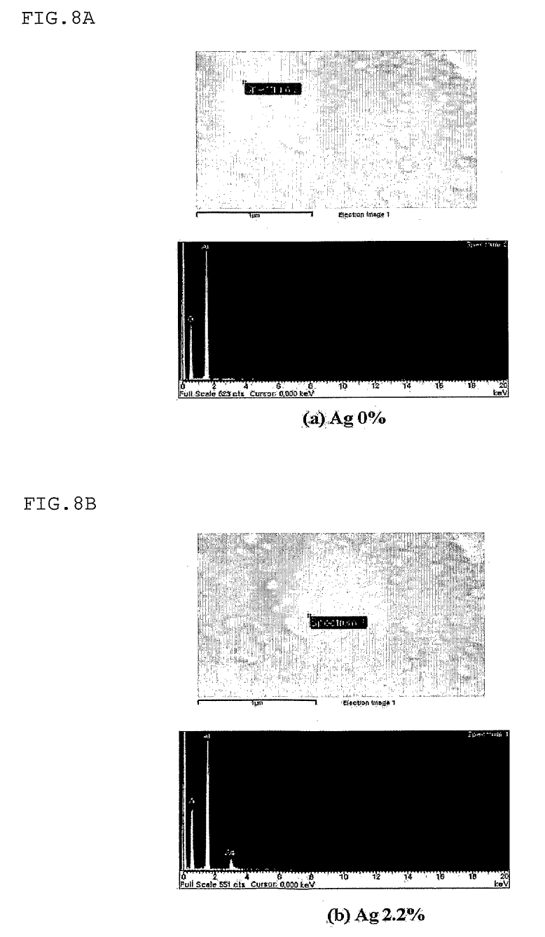

FIGS. 8A and 8B are a photograph and a graph of a chemical composition analysis result illustrating a surface of alumina powder on which the nano particles are not deposited, and a photograph and a graph of a chemical composition analysis result illustrating a surface of alumina powder on which the nano particles are deposited according to an exemplary embodiment of the present invention, respectively. In FIG. 8A, it can be appreciated that no silver (Ag) is observed in an alumina powder portion where the nano particles are not deposited. On contrary, in FIG. 8B, it can be appreciated that silver is observed in a nano particle portion, and particles on the alumina powder surface are the nano silver particles formed using vacuum deposition.

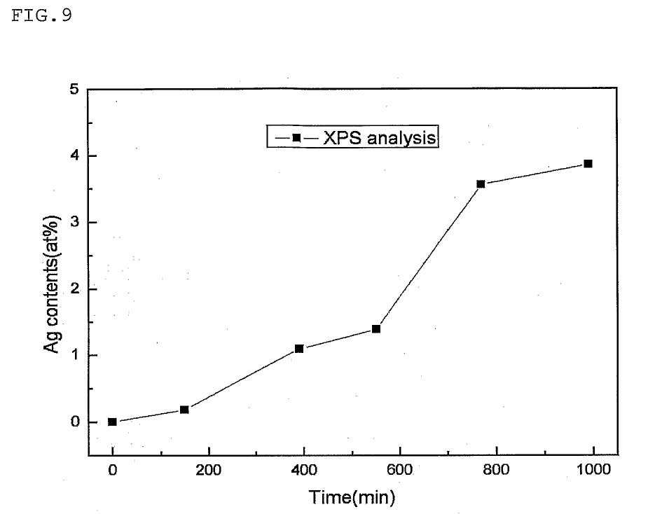

FIG. 9 is a graph illustrating an XPS measurement result obtained by measuring silver contents of the nano silver particles that are deposited on the alumina powder depending on the deposition time according to an exemplary embodiment of the present invention. It can be appreciated that the contents of silver deposited on the alumina powder are gradually monotone-increased depending on the deposition time. This means that the deposition time can simply vary, thereby easy controlling of desired contents of the nano particles is possible.

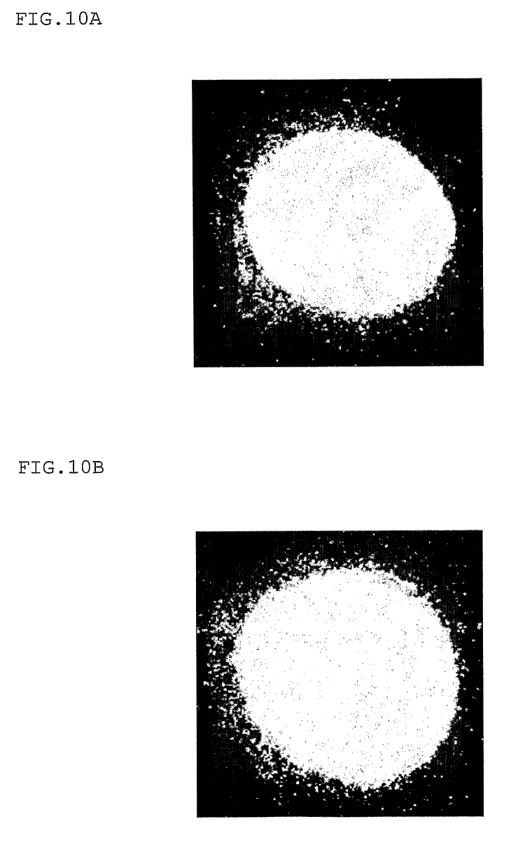

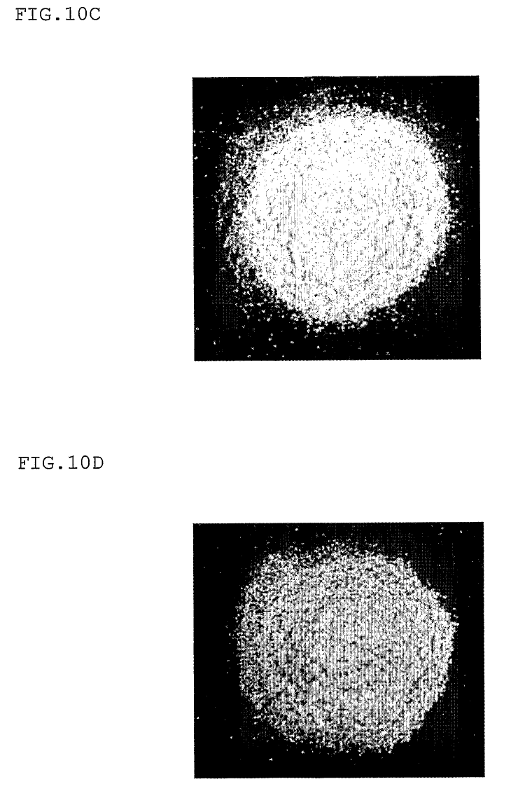

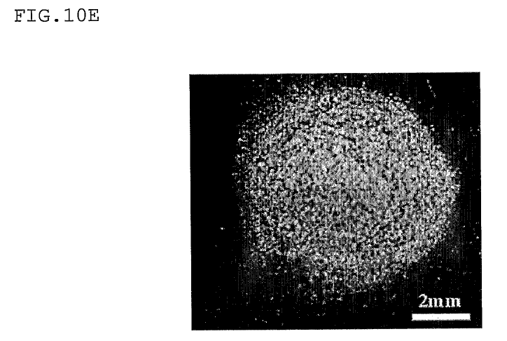

FIGS. 10A to 10E are practical photographs illustrating the alumina powder on which the nano silver particles are deposited depending on an increase of the same deposition time as FIG. 9, respectively. As shown in the drawings, as the contents of the nano silver particles increase, a color of the alumina powder gradually changes into a deep color. This is a result of the increase of the size of the nano silver particles based on an increase of the contents. Despite a long deposition time, the alumina powder on which the nano silver particles are deposited is tinged with yellow color. This is a typical color of the Ag nano particles having a small size of 200 nm or less. The color change is also exactly consistent with the SEM result of FIG. 5.

As described above, the present invention provides the method for preparing the nano metal, alloy, and ceramic particles, which are excellent in size uniformity, on the powder base using the vacuum deposition method, and identifies a feature of the nano particles prepared according to the present invention.

The present invention will be in detail described in exemplary embodiments below. But, the following embodiments are just only exemplary and are not intended to limit a scope of the present invention.

### FIRST EMBODIMENT

### Nano Silver Deposition on Salt and Sugar

About 25 kg of dried salt or sugar was put in the barrel 4 of FIG. 3, and a silver target was mounted on a DC magnetron sputter. After the powder was loaded in the vacuum chamber 1, a vacuum state was formed using the vacuum pump. A degree of vacuum is provided by only the low vacuum pump 3 or in combination with the high vacuum pump 2, depending on a work condition. An initial vacuum is kept in about 10⁻¹ to 10⁻⁶ torr. Sputtering gas employs argon (Ar) gas. An injection amount of argon gas can vary depending on the work condition. In general, injection is performed to keep a vacuum of about 10⁻¹ to 10⁻⁴ torr. After pumping to a desired vacuum degree and sputtering gas injection, silver target sputtering is performed, rotating the impeller 6 within the barrel 4. A rotation speed of the impeller 6 is controllable, and a sputtering speed is controllable depending on applied power and is generally within and out of a range of 1 W/cm² to 200 W/cm². The silver contents comparing to salt can vary depending on the work condition such as a sputtering power, a sputtering time, and the vacuum degree, and are generally controllable within a range of 10 ppm to 10000 ppm. The nano silver particles are also controllable in size depending on a mixture degree of salt and sugar based on the speed of the impeller 6 of the barrel 4 together with the work condition. Such a product can be used mixing with daily commodities, such as toothpaste, soap, and detergent, requiring anti-bacteria and sterilization, or can be used independently.

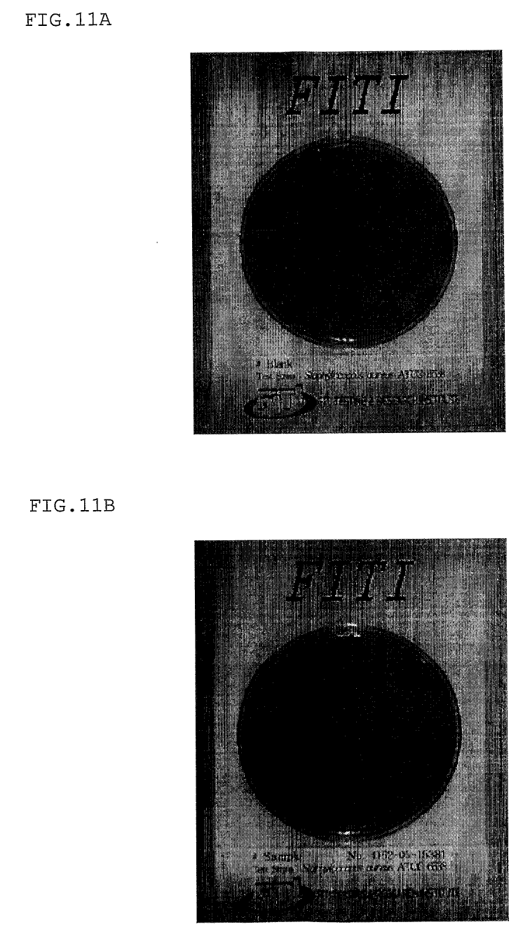

Table 1 shows an anti-bacteria test result of a soap sample prepared by mixing sugar on which the nano silver particles are deposited. As shown in the Table 1, it can be appreciated that, after 24-hour cultivation, the number of bacteria increases more than the initial number of bacteria in a sample (blank) to which the nano silver particles are not added. On contrary, it can be appreciated that, after 24-hour cultivation, bacteria are observed to decrease by 99.9% or more in a sample to which the nano silver particles are added, and the bacteria are all exterminated by addition of the nano silver particles. FIGS. 11A to 11B show the anti-bacteria test result of the soap sample of the Table 1. As described earlier, it can be appreciated that the number of bacteria is rapidly decreased in the soap sample containing the nano silver particles. Thus, it can be appreciated that the nano silver particle prepared according to the present invention has a sufficient anti-bacterial property.

TABLE 1
Anti-bacteria test result

| | Blank | Sample |
|---|---|---|
| Initial number | 1.4 × 10⁴ | 1.4 × 10⁴ |
| (bacteria number/ml) | | |
| After 24 hours | 2.1 × 10⁴ | <10 |
| (bacteria number/ml) | | |
| Percentage of reduction of | — | 99.9 |
| bacteria (%) | | |

Note)
1. Test condition: Shaking and cultivating a test bacteria liquid for 24 hours at a temperature of 37 ± 1° C., and then measuring the number of bacteria (Number of times of shaking: 120 times/minute)
2. Bacteria for public notice: Staphylococcus aureus ATCC 6538
3. Tested using a 1.0 g sample.

### SECOND EMBODIMENT

### Nano Silver Deposition on Activated Charcoal

About 20 kg of activated charcoal was provided in a barrel within a vacuum chamber, and silver nano particles were deposited on the activated charcoal using the same device and work condition as those of the first embodiment. If materials having a difficulty in obtaining the desired vacuum degree, a porous material such as the activated charcoal, perform the vacuum pumping, being heated by a heater installed over the barrel, they can easily perform the vacuum pumping within a little more fast time. Silver contents of the activated charcoal are controllable by varying a work condition such as a sputtering power, a sputtering time, an impeller rotation speed, and a vacuum degree, and are controllable within a range of 10 ppm to 1000 ppm. This can be used for an anti-bacteria and sterilization filter for a water purifier.

### THIRD EMBODIMENT

### Nano Silver Deposition on Sand

About 20 kg of sands were provided in a barrel 4 within a vacuum chamber 1, and nano silver particles were deposited on the sands using the same device and work condition as those of the first embodiment. In many cases, the sands generally contain much moisture. Thus, it is good to remove moisture from the sands using a dry process before providing the sands in the barrel 4 within the vacuum chamber 1. Moisture remaining even after the dry process is removed using a heater installed over the barrel 4, and a cold trap 10 within the vacuum chamber 1. The cold trap 10 can trap the moisture within the vacuum chamber 1 using a cold refrigerant and thus, can perform the vacuum pumping with a little more quickness. The silver contents of the sands are controllable by varying a work condition such as a sputtering power, a sputtering time, an impeller rotation speed, and a vacuum degree, and are controllable within a range of 10 ppm to 1000 ppm. This can be used for a place like a chicken farm or a stall owing anti-bacterial and sterilization functions, and can be also applied to a golf course.

### FOURTH EMBODIMENT

### Nano Silver Deposition on Titanium Oxide (TiO₂), Alumina (Al₂O₃)

About 20 kg of ceramic powder such as titanium oxide or alumina was provided in a barrel within a vacuum chamber 1 and nano silver particles were deposited on the ceramic powder using the same device and work condition as those of the first embodiment. It is desirable to use the TiO₂ and Al₂O₃ powders having a size of about 100 nm to 5 mm, not drifting even in a vacuum. Silver contents of the ceramic powder are controllable by varying a work condition such as a sputtering power, a sputtering time, an impeller rotation speed, and a vacuum degree, and are controllable within a range of 10 ppm to 10000 ppm. This is applicable to water treatment, anti-bacterial, and sterilization fields.

### FIFTH EMBODIMENT

### Nano Metal Particles Deposition on Silicon Dioxide (SiO₂)

About 20 kg of silicon dioxide powder was provided in a barrel 4 within a vacuum chamber 1, and metal nano particles were deposited using the same device and work condition as those of the first embodiment. It is desirable to use the SiO₂ powder of a size not drifting in a vacuum as in the fourth embodiment. The size is within or out of about 100 nm to 5 mm. Available metal is a kind of metal capable of serving as a catalyst for a nitride compound such as vanadium (V), manganese (Mn), nickel (Ni), and tungsten (W). Metal contents of the silicon dioxide powder are controllable by varying a work condition such as a sputtering power, a sputtering time, an impeller rotation speed, and a vacuum degree, and are controllable within a range of 10 ppm to 10000 ppm. This can be used as a catalyst for decomposition of a nitride compound such as nitric oxide (NO).

### SIXTH EMBODIMENT

### Nano Metal and Ceramic Particles Deposition on Zirconia (ZrO₂) and Iron Oxide (Fe₂O₃)

About 20 kg of zirconia or iron oxide powder was provided in a barrel 4 within a vacuum chamber 1, and nano metal or ceramic particles were deposited using the same device and work condition as those of the first embodiment. A target for deposition is gold (Au), platinum (Pt), ruthenium (Ru), stannum (Sn), palladium (Pd), cadmium (Cd), MgO, CaO, Sm₂O₃, and La₂O₃. Nano particle contents of the powder are controllable by varying a work condition such as a sputtering power, a sputtering time, an impeller rotation speed, and a vacuum degree, and are controllable within a range of 10 ppm to 10000 ppm. This is applicable as catalysts of an energy conversion field and a fuel cell, for inducing a reaction between petroleum and liquefied gas.

### SEVENTH EMBODIMENT

### Nano Metal Particles Deposition on Polymer Chip

About 20 kg of chip-typed PE, PP, PET, and PS was provided in a barrel 4 within a vacuum chamber 1, and nano metal particles were deposited using the same device and work condition as those of the first embodiment 1. A target for deposition is silver (Ag), gold (Au), and aluminum (Al). Nano particle contents of the powder are controllable by varying a work condition such as a sputtering power, a sputtering time, an impeller rotation speed, and a vacuum degree, and are controllable within a range of 10 ppm to 10000 ppm. In general, polymer materials have a weak adhesive strength with metal due to their low surface energies. For this, before the nano particles are deposited, a surface treatment for activating a surface of polymer material can be performed. A surface treatment method can employ an existing well-known ion beam assisted reaction, direct current/alternate current plasma or electron beam reaction method. Such chips having nano particles deposited can allow various products using a forming process. This is applicable to plastic home appliances, packing container, or decoration material requiring anti-bacteria and sterilization.

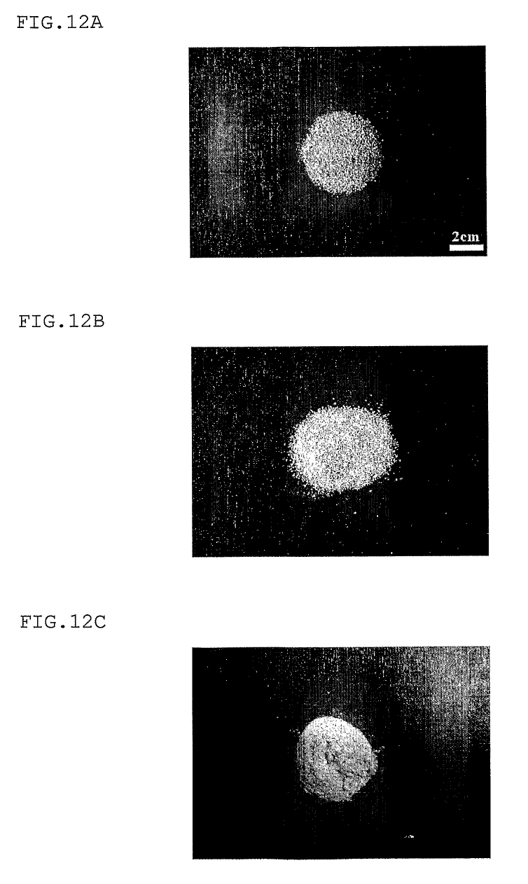

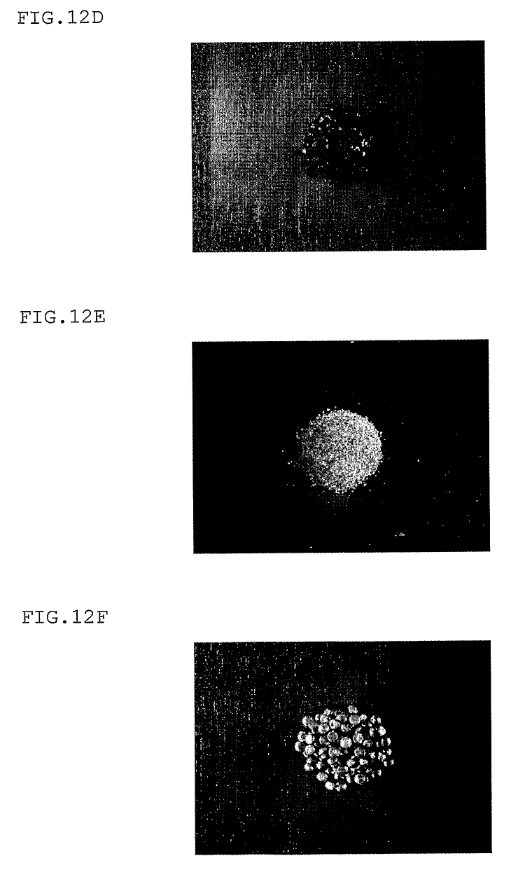

Practical figures illustrating various powder samples formed of sugar, salt, activated charcoal, Al₂O₃, sand, and PE chip having the nano particles, which are described in the respective exemplary embodiments, are shown in FIGS. 12A to 12F.

As described above, the present invention relates to the method for preparing the powder on which the nano, metal, alloy, and ceramic particles of the nanometer unit size are formed, and is a technique providing a variety of industrial applicability using the nano effect. The powder base on which the nano particles are formed can be directly used. In particular, in case where a soluble powder, such as sodium chloride (NaCl), potassium hydroxide (KOH), polyvinyl alcohol, sugar, aspartame, saccharin, and stevioside, is used as the base, the formed nano particles and powder base can be separated using a suitable solvent. From this, only pure nano metal, alloy, or ceramic particles can be obtained and applied. However, according to need, an appropriate dispersant for preventing the nano particles from cohering within the solution can be used.

The solvent necessary for dissolving the soluble powder employs all polar solvents such as distilled water, methyl alcohol, ethane alcohol, isopropyl alcohol, and acetone, and non-polar solvents such as hexane and benzene. An appropriate solvent can be selected and used depending on a kind of the soluble powder.

As the method for obtaining the nano particles from the soluble powder as described above, there can be a method for filtering the nano particles dispersed within the solution, using a well-known filter paper or filter device, and a method for diluting a concentration of the powder that corresponds to a solute within the solution, as much as possible, and then drying the diluted solution.

According to the present invention, the powder having the nano particles formed thereon and the nano particles separated from the powder are applicable to various fields as complete products, using deformation, mixing, dilution, and concentration processes depending on a characteristic and a usage of an application field.

### INDUSTRIAL APPLICABILITY

The present invention provides a device and a technology for preparing nano metal, alloy, and ceramic particles that are excellent in size uniformity, on a surface of a powder type base, using a vacuum deposition method. The present invention has an advantage that a high purity is obtained by using a vacuum deposition method, and no observation of a general cohesion phenomenon is made in the nano particles by performing a nano deposition on sand, thereby maximizing a nano effect. Various vacuum deposition methods can be used, and most materials such as metal, alloy, and ceramic can be formed as the nano particles. A production process can be highly simplified owing to the absence of chemical processing. By adjusting independently controllable process variables such as a sputtering power, a vacuum degree, and an agitation speed, a product having an excellent reproducibility can be prepared. In addition to a functionality of the existing powder base, a functionality of the nano particle is added, thereby making it possible to prepare multi-function powder. This is expected to be variously applicable to energy conversion field, fuel cell, and nitrogen compound decomposition-purposed catalyst fields, as well as daily commodities, wastewater processing, and optical catalyst fields requiring the anti-bacteria and sterilization.

While the present invention has been described and illustrated herein with reference to the preferred embodiments thereof, it will be apparent to those skilled in the art that various modifications and variations can be made therein without departing from the spirit and scope of the invention. Thus, it is intended that the present invention covers the modifications and variations of this invention that come within the scope of the appended claims and their equivalents.

1. A method for preparing powder on which nano metal, alloy, and ceramic particles are uniformly vacuum-deposited, the method comprising:
simultaneously performing, for a predetermined time, a step of vacuum-depositing the nano metal, alloy, and ceramic particles on a surface of the powder that is a base and a step of agitating the powder having the nano metal, alloy, and ceramic particles deposited, so that the nano metal, alloy, and ceramic particles having a uniform average diameter based on a nanometer unit are deposited on the powder surface.

2. The method according to claim 1, wherein the vacuum-depositing step of the nano metal, alloy, and ceramic particles is performed by a physical vapor deposition method or a chemical vapor deposition method.

3. The method according to claim 1, wherein the powder is of inorganic material or organic material of an average diameter of 100 nm to 5 mm, not evaporated in a vacuum.

4. The method according to claim 1, wherein the powder agitating step agitates the powder in three dimension using an agitating unit of a barrel type having a predetermined depth, so that, even though the powder having the nano particles deposited thereon is again exposed to a deposition zone, deposition particles reaching thereon are provided as independent nano particles without coalescence to an existing cluster.

5. The method according to claim 1, further comprising a step of drying the powder before the steps of vacuum-depositing the nano particles and agitating the powder.

6. The method according to claim 1, further comprising a step of activating the surface of the powder before the steps of vacuum-depositing the nano particles and agitating the powder.

7. The method according to claim 6, wherein the activating step of the powder surface is performed by an ion beam assisted reaction method and a direct current/alternate current plasma or electron beam reaction method.

8. A device for depositing nano metal, alloy, and ceramic particles on a surface of powder that is a base, using a vacuum deposition method, and preparing the powder on which nano metal, alloy, and ceramic particles are uniformly vacuum-deposited, the device comprises:
a vacuum chamber 1 for forming and keeping a vacuum;
a high vacuum pump 2 and a low vacuum pump 3 connecting to one exterior side of the vacuum chamber;
an agitating unit comprising a barrel 4 for containing the powder and an impeller 6 for agitating the powder;
a deposition unit 8 for vacuum-depositing metal, alloy, and ceramic materials;
a heating unit 9 for pre-treating the powder;
a cold trap 10 for removing moisture from the powder; and
a shield 7 for preventing the powder from diffusing outside the agitating unit at the time of agitation.

9. The device according to claim 8, wherein a coolant circulating passage 5 for supplying a coolant and offsetting a heat generated from the deposition unit 8 is provided outside the barrel 4.

10. The device according to claim 8, wherein the barrel 4, the impeller 6, and the vacuum chamber 1 are of stainless material.

11. The device according to claim 8, wherein the impeller 6 has a plurality of wings 6a on its circumferential surface and rotates in a predetermined direction, so that the powder can be uniformly mixed within the barrel 4.

12. The device according to claim 8, wherein the high vacuum pump 2 employs any one of an oil diffusion pump, a turbo pump, and a cryogenic pump.

13. The device according to claim 8, wherein the low vacuum pump 3 employs any one of a piston pump, a rotary pump, a booster pump, and a dry pump.

14. A method for preparing a solution containing nano metal, alloy, and ceramic particles, the method comprising:
simultaneously performing, for a predetermined time, a step of vacuum-depositing the nano metal, alloy, and ceramic particles on a surface of a soluble powder that is a base and a step of agitating the powder having the nano metal, alloy, and ceramic particles deposited, so that the nano metal, alloy, and ceramic particles having a uniform average diameter based on a nanometer unit are deposited on the powder surface; and
dissolving the soluble powder in a solvent.

15. A method for preparing nano metal, alloy, and ceramic particles, the method comprising:
simultaneously performing, for a predetermined time, a step of vacuum-depositing the nano metal, alloy, and ceramic particles on a surface of a soluble powder that is a base and a step of agitating the powder with the nano metal, alloy, and ceramic particles deposited, so that the nano metal, alloy, and ceramic particles having a uniform average diameter based on a nanometer unit are deposited on the powder surface; and
dissolving the soluble powder in a solvent, and separating non-dissolved nano particles from a solution.

16. The method according to claim 15, wherein the nano particles are separated from the solution by filtering.

17. The method according to claim 15, wherein the solution is diluted and dried, and the nano particles are separated from the solution.
